(19) United States
(12) Patent Application Publication
(10) Pub. No.: US 2025/0253148 A1
(43) Pub. Date: Aug. 7, 2025

(54) TRENCH AND CHANNEL GAP FILL TUNING FOR FLOWABLE CHEMICAL VAPOR DEPOSITION (FCVD) FILMS

(71) Applicant: Applied Materials, Inc., Santa Clara, CA (US)

(72) Inventors: PURVAM MODI, Sunnyvale, CA (US); BHARGAV CITLA, Fremont, CA (US); SRINIVAS NEMANI, Saratoga, CA (US); ELLIE YIEH, San Jose, CA (US)

(21) Appl. No.: 18/433,234

(22) Filed: Feb. 5, 2024

(51) Int. Cl. H01L 21/02; H01L 27/088; H01L 29/06; H01L 29/423; H01L 29/775; H01L 29/786

(52) U.S. Cl. CPC H01L 21/0234; H01L 21/0228; H10D 30/43; H10D 30/6735; H10D 30/6757; H10D 62/121; H10D 84/83

(57) ABSTRACT

Embodiments disclosed herein include a method for forming a film over a substrate. In an embodiment, the method comprises providing the substrate wherein the substrate comprises a trench and a channel into a sidewall of the trench, and disposing the film over the substrate. In an embodiment, the film flows into the channel and is disposed along the sidewall of the trench. In an embodiment, the method further comprises treating the film with a bias plasma treatment to solidify a portion of the film outside of the channel.

### BACKGROUND

### 1) Field

Embodiments relate to the field of semiconductor manufacturing and, in particular, apparatuses and methods for tuning the flowability of films deposited with flowable chemical vapor deposition (FCVD) processes for trench and channel deposition.

### 2) Description of Related Art

Semiconductor device architectures are increasingly moving towards the use of three-dimensional (3D) structures. As advances beyond fin-based transistors continue, architectures such as gate-all-around (GAA) transistors have been proposed. In GAA architectures, semiconductor sheets or semiconductor wires (e.g., nano-sheets or nano-wires) are provided in a stack within a fin. Lateral channels are provided between the nano-sheets. In order to isolate the nano-sheets, the lateral channels need to be filled with materials (e.g., insulators, dielectrics, conductors, etc.).

Existing film deposition processes do not currently allow for both high aspect ratio trench filling (i.e., between adjacent fins) while also allowing for complete filling of the lateral channels that traverse the fins. Conformal deposition processes (e.g., atomic layer deposition (ALD)) has been proposed. However, the conformal process may result in defects in the fill material within the lateral channel that can lead to reliability issues. When less conformal processes are used, tight pitches between fins can lead to pinch-off of the trench. This can lead to void formation within the device. Additionally, pitch non-uniformity between fins can lead to additional manufacturing limitations. For example, the thickness of the fill at the bottom of the trenches may be non-uniform. As such, removal of the fill may require a more complex etching process.

### SUMMARY

Embodiments disclosed herein include a method for forming a film over a substrate. In an embodiment, the method comprises providing the substrate wherein the substrate comprises a trench and a channel into a sidewall of the trench, and disposing the film over the substrate. In an embodiment, the film flows into the channel and is disposed along the sidewall of the trench. In an embodiment, the method further comprises treating the film with a bias plasma treatment to solidify a portion of the film outside of the channel.

Embodiments further comprise a method that comprises providing a substrate with a first trench with a first width and a second trench with a second width that is adjacent to the first trench. In an embodiment a channel connects the first trench to the second trench. In an embodiment, the method further comprises disposing a film over the substrate, wherein the film flows into the channel and is disposed along sidewalls of the first trench and the second trench, and along a bottom surface of the first trench and a bottom surface of the second trench. In an embodiment, the method further comprises treating the film with a bias plasma treatment to solidify a portion of the film in the first trench and the second trench. In an embodiment a first thickness of the film at the bottom surface of the first trench is substantially equal to a second thickness of the film at the bottom surface of the second trench.

Embodiments disclosed herein may also comprise a structure with a substrate, and a first fin and a second fin that extend up from the substrate. In an embodiment, the second fin is adjacent to the first fin. In an embodiment, a third fin that extends up from the substrate, and the third fin is adjacent to the second fin. In an embodiment, a channel is provided through the second fin, and a fill layer with a first material composition is in the channel. In an embodiment, the fill layer is seamless. In an embodiment, a liner is provided along sidewall surfaces of the first fin, the second fin, and the third fin. In an embodiment, the liner comprises a second material composition that comprises the same elements as the first material composition.

### BRIEF DESCRIPTION OF THE DRAWINGS

FIG. 1A is a cross-sectional illustration of a semiconductor device with a conformally deposited fill layer, in accordance with an embodiment.

FIG. 1B is a zoomed in cross-sectional illustration of a channel through a fin of the semiconductor device that illustrates the growth of the fill layer from the top and bottom of the channel, in accordance with an embodiment.

FIG. 1C is a zoomed in cross-sectional illustration of the channel through the fin of the semiconductor device after the fill layer is fully grown and a seam is provided through the fill layer, in accordance with an embodiment.

FIG. 2 is a cross-sectional illustration of a semiconductor device with a non-conformally deposited fill layer that suffers from non-uniform film thickness at the bottom of the trenches, in accordance with an embodiment.

FIG. 3 is a cross-sectional illustration of a semiconductor device with a non-conformally deposited fill layer that suffers from overburden at the top of the trenches that can result in void formation, in accordance with an embodiment.

FIG. 4A is a cross-sectional illustration of a semiconductor device with trenches between a plurality of fins and lateral channels that connect the trenches together through the fins, in accordance with an embodiment.

FIG. 4B is a cross-sectional illustration of the semiconductor device after a layer is deposited over the fins and the substrate with a flowable chemical vapor deposition (FCVD) process, in accordance with an embodiment.

FIG. 4C is a cross-sectional illustration of the semiconductor device after a plasma treatment of the layer that solidifies the portion of the layer outside of the lateral channels, in accordance with an embodiment.

FIG. 5A is an illustration of the chemical structure of the film layer while in a flowable state, in accordance with an embodiment.

FIG. 5B is an illustration of the plasma treatment used to break different types of chemical bonds that results in a solid film structure, in accordance with an embodiment.

FIG. 5C is an illustration of the solid film structure after the plasma treatment, in accordance with an embodiment.

FIG. 6 is a cross-sectional illustration of a chamber that may be used to implement the tunable FCVD process, in accordance with an embodiment.

FIG. 7 is a process flow diagram of a process that may be used to tune the gap fill properties of an FCVD process, in accordance with an embodiment.

FIG. 8 illustrates a block diagram of an exemplary computer system that may be used in conjunction with a processing tool, in accordance with an embodiment.

### DETAILED DESCRIPTION

Systems described herein include systems and methods for tuning the flowability of films deposited with flowable chemical vapor deposition (FCVD) processes for trench and channel deposition. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, three-dimensional (3D) semiconductor structures are of growing importance in the industry. 3D devices may include some memory structures or fin structures. Advances in processing performance have also resulted in the development of gate-all-around (GAA) structures. A GAA structure may include nano-sheets or nano-wires that are arranged in a stack within a fin-based structure. In order to provide gate control around the entire nano-sheet or nano-wire, lateral channels are provided across the thickness of the fin between the nano-sheets or nano-wires.

This leads to the problem of having two different types of structures (i.e., a vertical trench and a horizontal channel) that need to be filled for certain processing operations. Different form factors, aspect ratios, and/or directional orientations of these structures can result in different film deposition behaviors. For example, the high aspect ratio of the vertical trenches may benefit from a conformal deposition process, while the horizontal channels may benefit from a flowable deposition process. However, existing conformal deposition processes do not work well with flowable processes. As such, design tradeoffs are currently necessary.

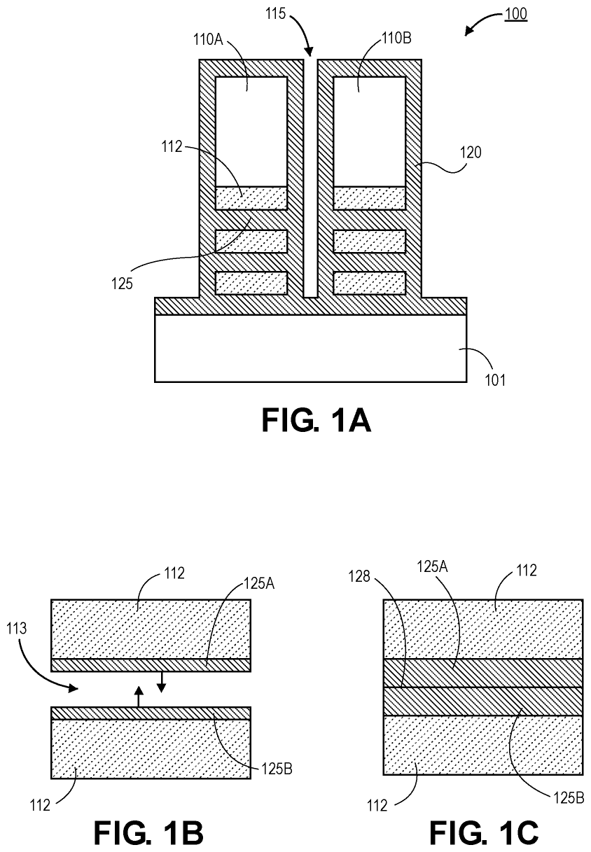

Referring now to FIG. 1A, a cross-sectional illustration of an idealized semiconductor device 100 is shown, in accordance with an embodiment. In an embodiment, the semiconductor device 100 may comprise a substrate 101. The substrate 101 may comprise a semiconductor substrate, or any other substrate material (or materials) used in semiconductor manufacturing processes. In an embodiment, a plurality of fins 110 may extend up from the substrate 101. For example, fin 110A and fin 110B may be provided over the substrate 101. The fins 110A and 110B may include semiconductor material (e.g., silicon) or any other suitable material. The fins 110A and 110B may be high aspect ratio features. For example, the height:width aspect ratio of the fins 110A and 110B may be approximately 5:1 or greater, approximately 10:1 or greater, approximately 20:1 or greater, or approximately 30:1 or greater. Though, embodiments may still be used with smaller aspect ratios. As used herein, “approximately” may refer to a range of values that are within ten percent of the state value. For example, “approximately 10:1” may refer to a ratio of 9:1 to 11:1.

In some embodiments, nano-sheets 112 (or nano-wires) may be provided as a stack within the fins 110A and 110B. The nano-sheets 112 may be a semiconductor material, such as silicon, a III-V semiconductor material, or the like. In an embodiment, the nano-sheets 112 may be a different material than the rest of the fins 110A or 110B. In an embodiment, the nano-sheets 112 within a single fin 110 may be separated from each other by a fill material 125. The fill material 125 may be an insulator, a dielectric, a conductor, or the like. In a particular embodiment, the fill material 125 may be the same material as a liner 120 that is provided along sidewalls of the fins 110A and 110B.

In the embodiment shown in FIG. 1A, the liner 120 and the fill material 125 are deposited with a conformal deposition process, such as an atomic layer deposition (ALD) process. The use of conformal deposition allows for high aspect ratio trenches 115 between fins 110 to be filled without pinching at the top (which would result in void formation between the fins 110). The fill material 125 also builds up from the surfaces of the nano-sheets 112 and can fill without significant risk of void formation.

However, it is to be appreciated that the semiconductor device 100 depicted in FIG. 1A is idealized. In reality, the use of a conformal deposition may result in significant defects within the channels between the nano-sheets 112. Examples of those defects are shown in FIGS. 1B and 1C.

Referring now to FIG. 1B, a zoomed in cross-sectional illustration of a pair of nano-sheets 112 that are stacked within a larger fin 110 (not shown) is shown, in accordance with an embodiment. As shown, the nano-sheets 112 are spaced apart from each other by a horizontal channel 113. During a conformal deposition process (e.g., an ALD process), fill material 125 deposits out from the exposed surfaces of the nano-sheets 112. For example, fill material 125A is growing down (as indicated by the arrow pointing down) from the top nano-sheet 112, and fill material 125B is growing up (as indicated by the arrow pointing up) from the bottom nano-sheet 112. The fill materials 125A and 125B may have a growth direction that is substantially normal to the plane of the exposed surface of the exposed surfaces of the nano-sheets 112. So long as gas species from the conformal deposition process can reach the growth front of the fill materials 125A and 125B, the deposition will continue.

Referring now to FIG. 1C, a zoomed in cross-sectional illustration of the nano-sheets 112 after complete growth of the fill materials 125A and 125B is shown, in accordance with an embodiment. In an embodiment, the fill material 125A and the fill material 125B may meet each other at a seam 128. The seam 128 may be substantially equally spaced from the top nano-sheet 112 and the bottom nano-sheet 112. In some instances, the seam 128 is substantially void-free. Though, voids may be present in some instances when fill material 125A and 125B growth is non-uniform.

However, even when there are no voids formed in the horizontal channel 113, manufacturing defects may still be present due to the formation of the seam 128 where the fill material 125A meets the fill material 125B. For example, the seam 128 may be a path of least resistance that can lead to shorting or other damage within the semiconductor device 100. As such, the reliability of the semiconductor device 100 is negatively impacted when conformal growth processes are used in order to fill the horizontal channel 113.

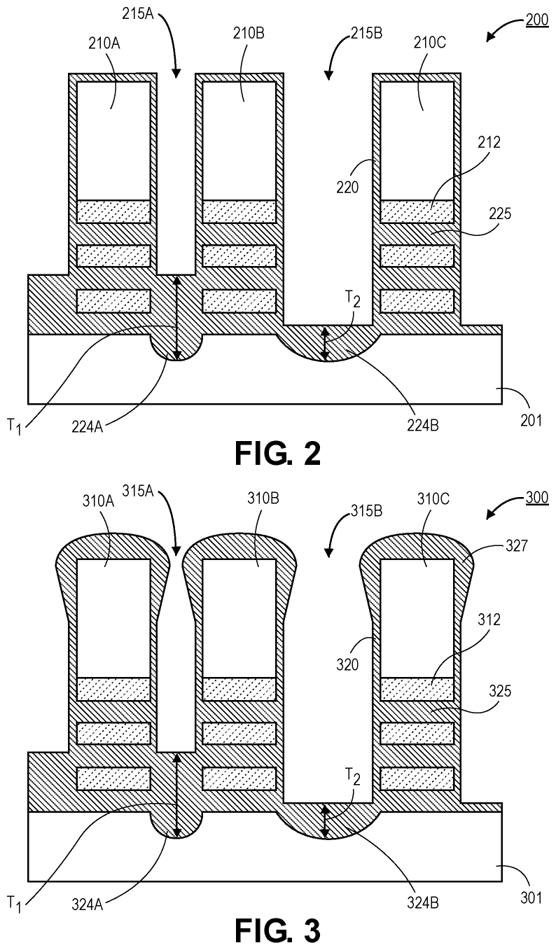

Accordingly, alternative approaches have been proposed for situations where high aspect ratio vertical trenches and horizontal channels both need to be filled. One proposed solution is to use a flowable deposition process. For example, a flowable chemical vapor deposition (FCVD) process can be used in order to deposit films that have properties similar to that of a liquid upon deposition (e.g., the film can flow), and the flow can then be halted during a solidification or curing process. This allows for a more complete bottom up filling process that is desirable for some applications. An example of an FCVD process is shown in FIG. 2.

Referring now to FIG. 2, a cross-sectional illustration of an idealized semiconductor device 200 is shown, in accordance with an embodiment. In an embodiment, the semiconductor device 200 may comprise a substrate 201. The substrate 201 may comprise a semiconductor substrate, or any other substrate material (or materials) used in semiconductor manufacturing processes. In an embodiment, a plurality of fins 210 may extend up from the substrate 201. For example fin 210A, fin 210B, and fin 210C may be provided over the substrate 201. The fins 210A-210C may be similar in structure to the fins 110 described in greater detail above.

In some embodiments, nano-sheets 212 (or nano-wires) may be provided as a stack within the fins 210A-210C. The nano-sheets 212 may be a semiconductor material, such as silicon, a III-V semiconductor material, or the like. In an embodiment, the nano-sheets 212 may be a different material than the rest of the fins 210A-210C. In an embodiment, the nano-sheets 212 within a single fin 210 may be separated from each other by a fill material 225. The fill material 225 may be an insulator, a dielectric, a conductor, or the like. In a particular embodiment, the fill material 225 may be the same material as a liner 220 that is provided along sidewalls of the fins 210A-210C.

In an embodiment, the liner 220 may be conformal to the sidewalls and top surface of the fins 210A-210C. However, the fill 224 at the bottom of the trenches 215A and 215B may be non-uniform. The non-uniform thickness of the fill 224A and 224B at the bottom of the trenches 215A and 215B may be the result of a non-uniform pitch between the fins 210. For example, a spacing between fin 210A and 210B may be smaller than a spacing between fin 210B and fin 210C. Due to the smaller spacing, the fill 224A may have a first thickness T₁ that is greater than a second thickness T₂ of the fill 224B.

Non-uniform fill thickness may be detrimental to the manufacturing process. For example, the fill 224A and 224B is often removed at some point during manufacturing with an etching process. Since the thicknesses of the fill 224A and 224B are different, the etching process is made more complex. That is, when the thinner fill 224B is fully removed, portions of the thicker fill 224A will still remain. This requires a longer etching duration, which may result in damage to the substrate 201 at the bottom of the trench 215B since the fill 224B has been fully removed.

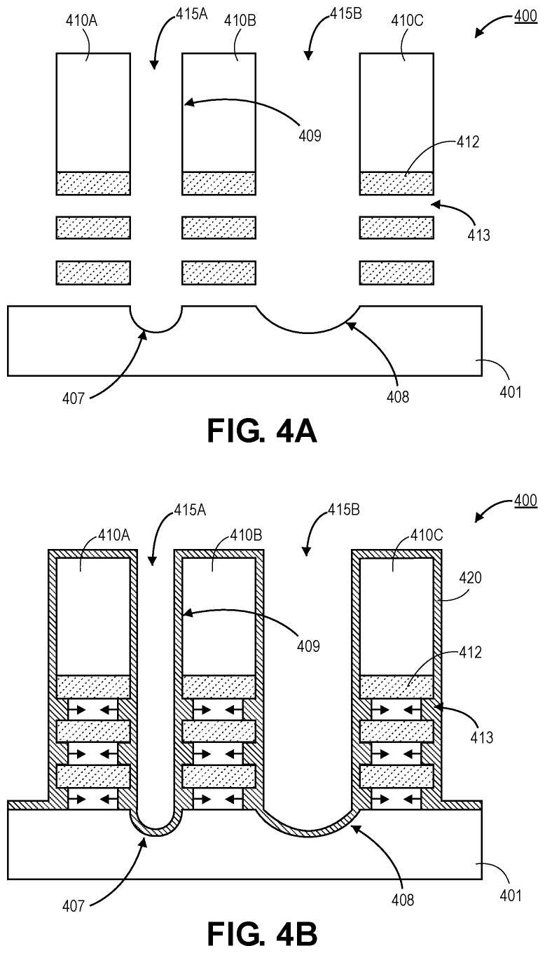

FCVD process may also suffer from trench pinch-off in some process regimes. That is, overburden near the top of neighboring fins may grow together and pinch off the rest of the trench. This can lead to void formation and/or otherwise result in incomplete filling of the vertical trench and/or the horizontal channels. An example of such an embodiment is shown in FIG. 3.

Referring now to FIG. 3, a cross-sectional illustration of an idealized semiconductor device 300 is shown, in accordance with an embodiment. In an embodiment, the semiconductor device 300 may comprise a substrate 301. The substrate 301 may be similar to any of the substrates described in greater detail herein. In an embodiment, a plurality of fins 310 may extend up from the substrate 301. For example fin 310A, fin 310B, and fin 310C may be provided over the substrate 301. The fins 310A-310C may be similar in structure to the fins 110 described in greater detail above.

In some embodiments, nano-sheets 312 (or nano-wires) may be provided as a stack within the fins 310A-310C. The nano-sheets 312 may be a semiconductor material, such as silicon, a III-V semiconductor material, or the like. In an embodiment, the nano-sheets 312 may be a different material than the rest of the fins 310A-310C. In an embodiment, the nano-sheets 312 within a single fin 310 may be separated from each other by a fill material 325. The fill material 325 may be an insulator, a dielectric, a conductor, or the like. In a particular embodiment, the fill material 325 may be the same material as a liner 320 that is provided along sidewalls of the fins 310A-310C.

In an embodiment, the liner 320 may not be perfectly conformal. For example, overhang 327 portions of the liner 320 may extend further away from the fins 310 than the rest of the liner 320. The overhang 327 may be more pronounced near an upper end of the fins 310. In the case of fins 310A and 310B with a small spacing between them (i.e., a narrow trench 315A), the overhang 327 may grow together and eventually pinch of the remainder of the trench 315A. The rest of the trench 315A may then have a void and/or otherwise include incomplete filling. This void formation can provide reliability concerns.

Similar to the embodiment shown in FIG. 2, the non-uniform spacing of fins 310A-310C may result in trenches 315A and 315B that have non-uniform fill 324 thicknesses. For example, narrower trench 315A may have fill 324A with a first thickness T₁ that is greater than second thickness T₂ of a fill 324B of the wider trench 315B. Accordingly, the embodiment shown in FIG. 3 may suffer from both void formation and manufacturing difficulties produced due to fill 324 thickness variations.

Accordingly, embodiments disclosed herein include an FCVD process that can be tuned in order to allow for adequate flow characteristics to fill horizontal channels, while maintaining a more conformal fill within the vertical trenches. This allows for the deposition of films with improved reliability and manufacturing simplicity. The FCVD process disclosed herein is different from previous attempts in that a bias plasma treatment is added into the process flow. For example, the process may comprise: 1) an FCVD deposition; and 2) a bias plasma treatment after the FCVD deposition. The two operations may be repeated any number of times.

The FCVD treatment deposits a flowable polymer material. Due to capillary forces, the deposited material may fill horizontal channels. The Bias treatment is a directional, line-of-sight, treatment that alters the chemistry and solidifies the deposited material. Since the treatment is line-of-sight, the material within the horizontal channels is not altered and is still able to flow. This allows for a void free fill in the horizontal channels, while a conformal deposition is enabled in the vertical trenches.

Embodiments disclosed herein may include tunable FCVD film deposition for a wide variety of material compositions. For example, dielectric materials that may be compatible with such processes may include films comprising: 1) silicon and oxygen (e.g., SiO); 2) silicon, oxygen, and carbon (e.g., SiOC); 3) silicon, oxygen, carbon, and nitrogen (e.g., SiOCN); 4) silicon, oxygen, and nitrogen (e.g., SiON), and/or the like. A wide variety of precursors may also be used in order to deposit such films. In an embodiment, the bias plasma treatment may use source gasses, such as one or more of He, Ar, N₂, NH₃, O₂, or H₂.

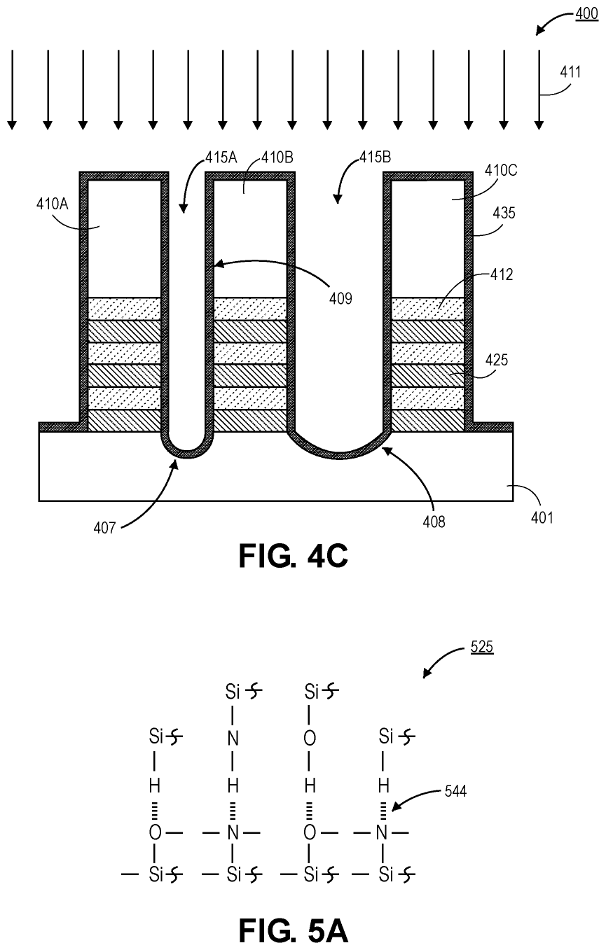

Referring now to FIGS. 4A-4C, a series of cross-sectional illustrations depicting different operations in a tunable FCVD deposition process is shown, in accordance with an embodiment. In the embodiment shown in FIGS. 4A-4C, the structure of the semiconductor device 400 is generally shown as a GAA transistor structure with stacked nano-sheets 412 within the fins 410. However, the tunable FCVD process may be applicable to any surface structure that may include 3D structures with different fill requirements. For example, a surface structure that comprises both a trench and a horizontal channel extending into a sidewall of the trench may benefit from embodiments disclosed herein. In some embodiments, 3D memory structures may benefit from embodiments disclosed herein.

Referring now to FIG. 4A, a cross-sectional illustration of a semiconductor device 400 is shown, in accordance with an embodiment. In an embodiment, the semiconductor device 400 may comprise a substrate 401. The substrate 401 may be similar to any of the substrates described in greater detail herein. In an embodiment, a plurality of fins 410 may extend up from the substrate 401. For example fin 410A, fin 410B, and fin 410C may be provided over the substrate 401. The fins 410A-410C may be similar in structure to the fins 110 described in greater detail above.

In some embodiments, nano-sheets 412 (or nano-wires) may be provided as a stack within the fins 410A-410C. The nano-sheets 412 may be a semiconductor material, such as silicon, a III-V semiconductor material, or the like. In an embodiment, the nano-sheets 412 may be a different material than the rest of the fins 410A-410C. In an embodiment, the nano-sheets 412 within a single fin 410 may be separated from each other by channels 413. While shown as “floating” in the illustrated cross-section, it is to be appreciated that the fins 410 and the stacked nano-sheets 412 are secured by structures out of the plane of FIG. 4A.

In an embodiment, the channels 413 may extend into and through a thickness of the fins 410. That is, channels 413 may be considered as “connecting” adjacent trenches 415 together. For example, channels 413 in the fin 410B may connect the trench 415A to the trench 415B. The channels 413 may extend into sidewalls 409 of the trenches 415. In some embodiments, the channels 413 extend into the fins 410 in a direction that is substantially orthogonal to a plane of the sidewall 409 of the trenches 415. Though, the orientation of the channel 413 and the trench 415 may be non-orthogonal in other embodiments. In an embodiment, a thickness of the channels 413 (e.g., a distance between stacked nano-sheets 412) may be up to approximately 20 nm, up to approximately 10 nm, or up to approximately 5 nm. Though, larger channels 413 may also be used in some embodiments.

In an embodiment, the trenches 415 may also comprise bottom surfaces (e.g., surface 407 at the bottom of trench 415A, or surface 408 at the bottom of trench 415B). The surfaces 407 and 408 may be recessed surfaces from a top of the substrate 401. Though, in other embodiments, the bottom of the trenches 415 may be the top surface of the substrate 401.

In an embodiment, the fins 410 may have non-uniform spacings or pitches. For example, the non-uniform spacing of fins 410A-410C may result in trenches 415A and 415B that have different widths. However, as will be described in greater detail below, the different widths of the trenches 415A and 415B may not result in different film thicknesses at bottoms of the trenches 415A and 415B since the tunable FCVD process is more conformal than previous solutions.

Referring now to FIG. 4B, a cross-sectional illustration of the semiconductor device 400 after a film deposition process is shown, in accordance with an embodiment. In an embodiment, the film deposition process is an FCVD process. In an FCVD process, the film is deposited in a polymeric state that has flowability properties that are similar to those of a liquid. As such, surface tension forces tend to attract the film 420 to the sidewalls 409 of the trenches 415A and 415B. The film 420 may also deposit over the bottom surfaces 407 and 408 between fins 410. Due to the flowable nature of the film 420, the material does not preferentially build up near the top of the fins 410. As such, there is no pinching that can lead to void formation within the trenches 415.

The film 420 may also span across the channels 413. As indicated by the arrows, the film 420 is drawn into the channels 413 due to capillary forces or the like. As such, small openings can be fully filled with a liquid like film. In FIG. 4B, the film 420 partially fills the channels 413. However, over time, the film may fully fill the channels 413, as will be described in greater detail herein.

Referring now to FIG. 4C, a cross-sectional illustration of the semiconductor device 400 during a bias plasma treatment is shown, in accordance with an embodiment. The bias plasma treatment may result in ions 411 being directed towards the semiconductor device 400. The ions 411 may interact with the film 420 in order to form a treated film 435. The treated film 435 may lose the characteristic flowability of the original film 420. This is accomplished through the ions 411 breaking bonds (e.g., hydrogen bonds, dangling bonds, etc.) that otherwise prevent cross-linking. In an embodiment, the ions 411 may comprise any suitable ion type, such as helium ions, argon ions, or the like.

As shown in FIG. 4C, the ions 411 interact with the semiconductor device 400 with a vertical trajectory with respect to the surface of the substrate 401. In an embodiment, the ions 411 may have some angular offset as well. For example, the angular offset may be within 20° of vertical, within 10° of vertical, or within 5° of vertical. The angular offset may allow for the ions 411 to interact with the film 435 along the sidewalls 409 of the trenches 415.

However, even with some amount of angular offset, the film 425 within the channels 413 may be substantially unaltered. As such, the film 425 within the channels 413 will remain in a flowable state. This allows for complete filling of the channels 413 with a seamless and/or voidless structure. Accordingly, the reliability of the structure is improved compared to existing solutions.

Further, embodiments disclosed herein may include compositional and/or structural differences between the film 425 within the channels 413 and the treated film 435, even though they are deposited with the same FCVD process and precursors. For example, during the bias plasma treatment, the treated film 435 may densify due to elimination of Si—H bonds, SiO—H bonds, SiN—H bonds, and/or the like. Stated differently, the film 425 may have a first material composition, and the treated film 435 may have a second material composition. The first material composition and the second material composition may both comprise the same elements, but a concentration of each of the elements may be different. For example, the first material composition of the film 425 may have a higher hydrogen concentration than a hydrogen concentration in the treated film 435.

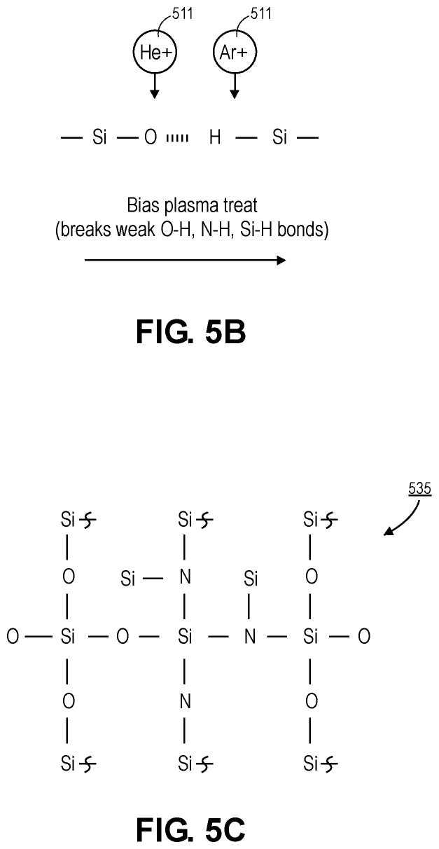

Referring now to FIGS. 5A-5C, a series of schematics illustrating the bias plasma treatment process at an elemental level is shown, in accordance with an embodiment.

Referring now to FIG. 5A, a chemical structure of an FCVD deposited film 525 is shown, in accordance with an embodiment. In the particular embodiment shown in FIG. 5A, the chemical structure of the film illustrates an SiON network in a flowable state. For example, weak hydrogen bonds 544 prevent the strong cross-linking bonds that may otherwise be generated between elements such as silicon, nitrogen, and oxygen. Without the cross-linking, the film 525 remains in a flowable state.

Referring now to FIG. 5B, an illustration of the bias plasma treatment is shown, in accordance with an embodiment. As shown, the ions 511 are directed toward the chemical structure. The ions 511 may interact with the bonds in order to break the weaker bonds based on hydrogen bonding. That is, O—H bonds, N—H bonds, Si—H bonds, dangling bonds, and/or the like are more susceptible to damage. When the hydrogen is removed, the remaining elements are more reactive and initiate cross-linking reactions. The ions 511 may include any suitable inert ions, such as helium ions, argon ions, and/or the like.

Referring now to FIG. 5C, an illustration of the treated film 535 is shown, in accordance with an embodiment. As shown, hydrogen has been removed, and the hydrogen bonds are replaced with Si—N bonds, Si—O bonds, and/or the like. These stronger bonds increase cross-linking of the treated film 535 and eliminate the ability to flow. That is, the treated film 535 may be considered as being “frozen” or “solidified” in some embodiments.

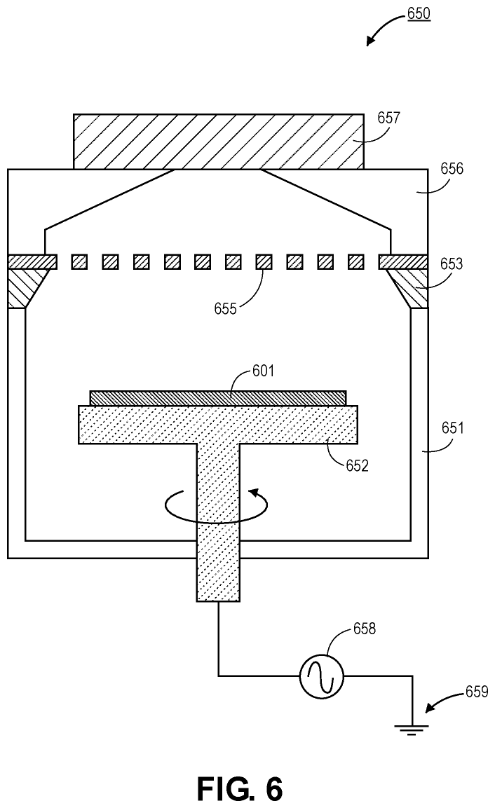

Referring now to FIG. 6, a cross-sectional illustration of a tool 650 is shown, in accordance with an embodiment. In an embodiment, the tool 650 May be a tool compatible with tunable FCVD processes, such as those described in greater detail herein. For example, the tool 650 may comprise a chamber 651 capable of supporting a vacuum environment. A spacer 653 may support a showerhead 655, and an enclosure 656 or lid may cover the showerhead 655. A plasma source 657 may be coupled to the enclosure 656. The plasma source 657 may be a remote plasma source (RPS), an inductively coupled plasma (ICP) source, a capacitively coupled plasma (CCP) source, a microwave plasma source, or any other suitable plasma source.

In an embodiment, plasma generated by the plasma source 657 may be a source of ions that propagate through the showerhead 655 towards the substrate 601, which is on a pedestal 652. The plasma may be used as part of the FCVD process in some embodiments. The plasma may also be used as part of the bias plasma process. For example, different source gasses may be fed to tool 650 in order to generate a desired plasma. For example, precursor gasses may be fed into the chamber 651 for the FCVD process, and inert source gasses (e.g., He, Ar, N₂, NH₃, O₂, H₂, etc.) may be fed into the chamber 651 for the bias plasma process. In an embodiment, the pedestal 652 may be rotatable, as indicated by the arrow.

In an embodiment, a bias 658 may be coupled between the pedestal 652 and a ground 659. The bias 658 may be a pulsed bias 658, such as an RF pulsed bias 658. For example, the RF pulsed bias 658 may include a 2 MHz frequency. The bias 658 may also comprise a 13.56 MHz pulsed bias. Though, any suitable frequency may be used in accordance with embodiments disclosed herein.

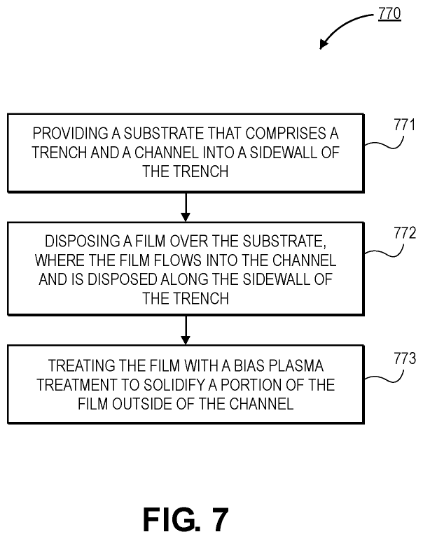

Referring now to FIG. 7, a process flow diagram of a process 770 for depositing a film with a tunable FCVD process is shown, in accordance with an embodiment. In an embodiment, the process 770 may begin with operation 771, which comprises providing the substrate that comprises a trench and a channel into a sidewall of the trench. In an embodiment, the substrate may be similar to any of the semiconductor devices described in greater detail herein. For example, the trench may be a feature provided between a pair of fins that extend up from the substrate, and the channel may extend into (and/or pass through) one of the fins. Other substrate architectures may also be used, such as architectures for 3D memory semiconductor devices and/or any 3D semiconductor structures.

In an embodiment, the process 770 may continue with operation 772, which comprises disposing a film over the substrate. In an embodiment, the film may be deposited with an FCVD process. That is, one or more precursor gasses may be flown into a chamber, and the one or more precursor gasses react and/or are ionized in order to form a flowable film. In an embodiment, the film flows into the channel and is disposed along the sidewall of the trench.

In an embodiment, the film may have a composition that comprises one or more of: 1) silicon and oxygen (e.g., SiO); 2) silicon, oxygen, and carbon (e.g., SiOC); 3) silicon, oxygen, carbon, and nitrogen (e.g., SiOCN); 4) silicon, oxygen, and nitrogen (e.g., SiON), and/or the like. The composition of the film may also comprise hydrogen in addition to one or more of silicon, oxygen, carbon, or nitrogen. In order to form such films, one or more different precursor chemistries may be used. For example, trisilyl amine may be used to form a SiON film, tetravinyl silane may be used to form a SiC film, 1,3-divinyl-1,1,3,3-tetramethyl disilazane may be used to form a SiCN film, 1,3,5-trivinyl-1,3,5-trimethylcyclotrisilazane may be used to from a SiCN film, or tetramethyl orthosilicate may be used to form a SiOC film. Though, other precursors or combinations of multiple precursors may also be used in some embodiments.

Processing conditions for the film deposition may be any suitable processing conditions. For example, temperatures of the substrate may be maintained relatively low (e.g., less than approximately 100° C.), and pressures may be provided between approximately 100 mTor and 10 Tor. Though, higher temperatures and pressures outside of the stated range may also be used in some embodiments. The substrate may also be rotated during deposition in order to improve deposition uniformity across the substrate.

In an embodiment, the process 770 may continue with operation 773, which comprises treating the film with a bias plasma treatment to solidify a portion of the film outside of the channel. In an embodiment, the bias plasma treatment includes ionizing one or more inert gasses (e.g., He, Ar, N₂, NH₃, O₂, or H₂, etc.) and using the bias to direct the ions toward the substrate. The ions bombard the portions of the film outside of the channel. As described in greater detail above, the bombardment breaks weaker hydrogen bonds. The unterminated elements (e.g., silicon, nitrogen, carbon, oxygen, etc.) are then more reactive and tend to initiate cross-linking reactions. The cross-linking solidifies the portion of the film outside of the channel.

Accordingly, the film within the channel may remain flowable in order to provide a complete fill of the channel that is void free and seam free. The solidified portion of the film outside of the channel minimizes the formation of overhang at the top of the trench. This limits or eliminates void formation in the trench. Additionally, film thicknesses at the bottom of the trenches are substantially uniform across the substrate, even when fin spacings or pitches are non-uniform.

In an embodiment, the process 770 may cycle operations 772 and 773 any number of times. For example, a cyclical process of FCVD deposition (in a flowable state) followed by a bias plasma treatment may be implemented a plurality of times. Repeating the process may allow for thicker films to be deposited while still allowing for the desired tunability in the film to enable the fill of both horizontal channels and vertical trenches.

Embodiments disclosed herein are also beneficial to the semiconductor device because the deposition process mitigates or avoids damage to the fins (and the stacked nano-sheets within the fins). For example, the bias plasma process may be a pulsed bias plasma in order to reduce damage to the underlying structure. The low temperature conditions may also protect the underlying structure.

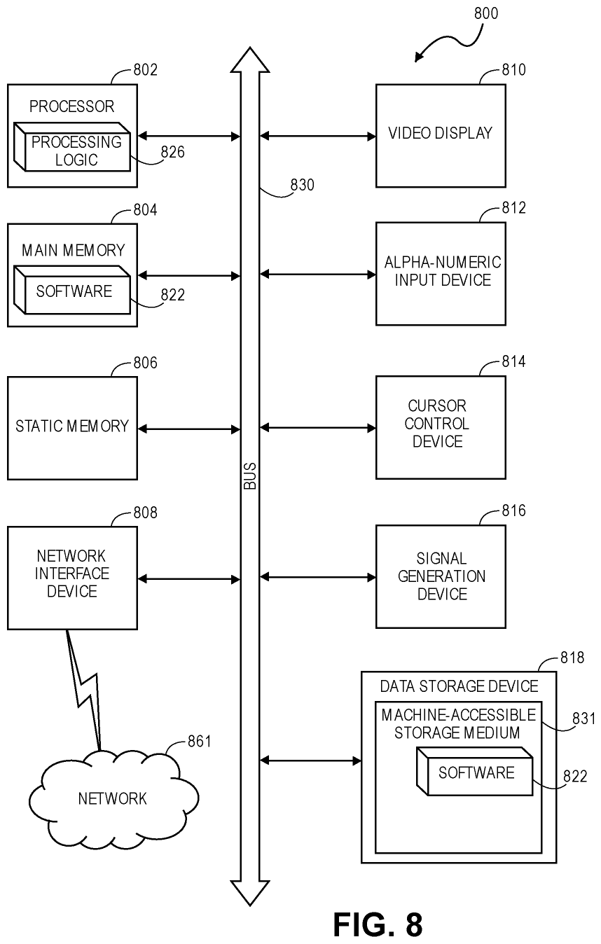

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of forming a film over a substrate, comprising:
depositing a film over the substrate, wherein the substrate comprises a trench and a channel into a sidewall of the trench, and wherein the film flows into the channel and is disposed along the sidewall of the trench; and
treating the film with a bias plasma treatment to solidify a portion of the film outside of the channel.

2. The method of claim 1, wherein the film is disposed over the substrate with a flowable chemical vapor deposition (FCVD) process.

3. The method of claim 1, wherein the film comprises one or more of: silicon and oxygen; silicon, oxygen, and carbon; or silicon, oxygen, carbon, and nitrogen.

4. The method of claim 1, wherein the channel is a horizontal channel that extends in a direction that is substantially orthogonal to the sidewall of the trench.

5. The method of claim 1, wherein the bias plasma treatment comprises a use of ions comprising one or more of He, Ar, N₂, NH₃, O₂, or H₂.

6. The method of claim 1, wherein the bias plasma treatment is a pulsed treatment.

7. The method of claim 1, wherein a second portion of the film within the channel is seamless.

8. The method of claim 1, wherein the substrate comprises a nano-sheet structure or a nano-wire structure.

9. The method of claim 1, wherein the substrate comprises a three dimensional memory structure.

10. The method of claim 1, further comprising:
repeating operations of disposing the film and treating the film two or more times.

11. A method, comprising:
depositing a film over a substrate, wherein the substrate comprises a first trench with a first width and a second trench with a second width that is adjacent to the first trench, and wherein a channel connects the first trench to the second trench, and wherein the film flows into the channel and is disposed along sidewalls of the first trench and the second trench, and along a bottom surface of the first trench and a bottom surface of the second trench; and
treating the film with a bias plasma treatment to solidify a portion of the film in the first trench and the second trench, wherein a first thickness of the film at the bottom surface of the first trench is substantially equal to a second thickness of the film at the bottom surface of the second trench.

12. The method of claim 11, wherein the film is deposited with a flowable chemical vapor deposition (FCVD) process.

13. The method of claim 11, wherein the film comprises one or more of: silicon and oxygen; silicon, oxygen, and carbon; or silicon, oxygen, carbon, and nitrogen.

14. The method of claim 11, wherein a nano-sheet or nano-wire device is provided between the first trench and the second trench.

15. The method of claim 11, wherein an aspect ratio (depth:width) of the first trench is 5:1 or greater.

16. The method of claim 11, wherein the bias plasma treatment comprises a use of ions comprising one or more of He, Ar, N₂, NH₃, O₂, or H₂.

17. A structure, comprising:
a substrate;
a first fin that extends up from the substrate;
a second fin that extends up from the substrate, and wherein the second fin is adjacent to the first fin;
a third fin that extends up from the substrate, and wherein the third fin is adjacent to the second fin;
a channel through the second fin;
a fill layer with a first material composition in the channel, wherein the fill layer is seamless; and
a liner along sidewall surfaces of the first fin, the second fin, and the third fin, wherein the liner comprises a second material composition that comprises the same elements as the first material composition.

18. The structure of claim 17, wherein a percentage of one or more elements in the first material composition is different than a percentage of the same one or more elements in the second material composition.

19. The structure of claim 17, wherein the fill layer is provided between semiconductor nano-sheets within the second fin.

20. The structure of claim 17, wherein a first spacing between the first fin and the second fin is different than a second spacing between the second fin and the third fin.
